(19) United States
(12) Patent Application Publication
(10) Pub. No.: US 2026/0090309 A1
(43) Pub. Date: Mar. 26, 2026

(54) THINNED SUBSTRATE MANUFACTURING METHOD

(71) Applicant: DISCO CORPORATION, Tokyo (JP)

(72) Inventor: Yoshinobu Saito, Tokyo (JP)

(21) Appl. No.: 19/306,460

(22) Filed: Aug. 21, 2025

(30) Foreign Application Priority Data
Sep. 24, 2024 (JP) 2024-165289

(51) Int. Cl. H01L 21/78; H01L 21/683

(52) U.S. Cl. CPC H10P 54/00; H10P 72/7402

(57) ABSTRACT

A manufacturing method of a second substrate by separating, as the second substrate, a part of a small thickness portion of a first substrate including a protruding portion and the small thickness portion surrounded by the protruding portion, the first substrate having one surface to which a protective member is fixed, includes setting an inner circumferential edge of a removal region in the small thickness portion, where the inner edge defines an external shape of the second substrate, setting an outer circumferential edge of the removal region such that the outer edge of the removal region is located at a middle point between the inner edge and a boundary between the small thickness portion and the protruding portion or located outward of the middle point in a radial direction of the first substrate, and separating the second substrate from the first substrate by removing the removal region.

### BACKGROUND OF THE INVENTION

### Field of the Invention

The present invention relates to a manufacturing method of manufacturing a second substrate by separating, as the second substrate, a part of a small thickness portion of a first substrate including a protruding portion formed along an outer circumferential edge and a small thickness portion having an outside surrounded by the protruding portion, the first substrate having one surface to which a protective member is fixed, a manufacturing method of manufacturing a plurality of chips from the first substrate, and a setting method of setting a removal region in the first substrate in order to separate a part of the small thickness portion of the first substrate as the second substrate.

### Description of the Related Art

A proposal has been made of subjecting a wafer to processing after forming, in the wafer, an annular protruding portion (that is, a ring-shaped reinforcing portion) and a small thickness portion having an outside surrounded by the protruding portion, by thinning a central portion of the wafer without thinning an outer circumferential portion of the wafer, in order to ensure rigidity of the wafer in a manufacturing step (see Japanese Patent Laid-open No. 2022-114113, for example).

In this wafer, the small thickness portion and the annular protruding portion define a recessed portion located in a central portion of the back surface of the wafer. Incidentally, a central portion of the front surface of the wafer, which central portion is located on the central side of the protruding portion in the radial direction of the wafer, is generally regularly provided with a plurality of devices.

Before this wafer is finally divided into the plurality of devices, the protruding portion is separated from the wafer (separating step). In order to perform the separating step, first, a central portion of a thin protective member made of resin is affixed to the back surface of the wafer, and a ring frame made of metal is affixed to an outer circumferential portion of the protective member. At this time, the protective member is affixed so as to conform to the recessed portion of the wafer.

Next, the separating step is performed by using a laser processing apparatus, for example. In the separating step, a wafer unit in which the wafer and the ring frame are integrated with each other via the protective member is held under suction by a holding plate of the laser processing apparatus such that the front surface of the wafer is exposed.

Incidentally, the diameter of a holding surface of the holding plate is smaller than the diameter of the recessed portion. Thus, when the wafer is held under suction by the holding plate, the holding surface disposed within the recessed portion holds the small thickness portion of the wafer under suction via the protective member. At this time, the protruding portion of the wafer is disposed radially outward of the holding surface.

Then, a laser-processed groove is formed in the small thickness portion by ablation processing so as to penetrate the small thickness portion in the thickness direction of the wafer, by irradiating an outer circumferential portion of the small thickness portion with a laser beam having a wavelength to be absorbed by the wafer.

Next, the adhesive force of the protective member is reduced in an annular region located radially outward of the holding plate, and then the protruding portion is removed from the protective member. A thinned wafer is thereby obtained which has a smaller diameter than the original wafer and corresponds to a central portion of the small thickness portion. A plurality of device chips are manufactured by dividing the thinned wafer into device units by using a dicing apparatus after the separating step.

Now, when the separating step forms the laser-processed groove in the wafer including the protruding portion and the thin portion, an outer circumferential portion of the small thickness portion generally remains on the outside of the laser-processed groove in the radial direction of the wafer. The small thickness portion remaining on the outside of the laser-processed groove is weak in strength due to the thinness of the small thickness portion. The small thickness portion therefore tends to be cracked in the laser processing step and subsequent steps.

Fragments produced by the cracking of the small thickness portion may be peeled off from the protective member and enter the inside of a processing apparatus such as the laser processing apparatus or the dicing apparatus. The fragments of the small thickness portion enter the inside of the processing apparatus in unexpected timing, for example, when the thinned wafer after laser processing is unloaded from the laser processing apparatus or when the thinned wafer is loaded into the dicing apparatus. When the fragments of the small thickness portion, which fragments are peeled off from the protective member, enter the inside of the processing apparatus, the trouble of cleaning the inside of the processing apparatus arises, consequently decreasing productivity.

### SUMMARY OF THE INVENTION

The present invention has been made in view of such problems. It is an object of the present invention to reduce a possibility of fragments of the small thickness portion being peeled off from the protective member.

In accordance with an aspect of the present invention, there is provided a manufacturing method of manufacturing a second substrate by separating, as the second substrate, a part of a small thickness portion of a first substrate including a protruding portion formed along an outer circumferential edge and the small thickness portion having an outside surrounded by the protruding portion, the first substrate having one surface to which a protective member is fixed, the manufacturing method including setting an inner circumferential edge of a removal region in the small thickness portion, the inner circumferential edge being configured to define an external shape of the second substrate, setting an outer circumferential edge of the removal region in the first substrate such that the outer circumferential edge of the removal region is located at a middle point between the inner circumferential edge of the removal region and a boundary between the small thickness portion and the protruding portion or located outward of the middle point in a radial direction of the first substrate, and separating the second substrate from the first substrate by removing the removal region in a thickness direction of the first substrate.

Preferably, in setting the outer circumferential edge of the removal region in the first substrate, the outer circumferential edge of the removal region is set at a position corresponding to the boundary.

In addition, preferably, the manufacturing method further includes peeling off the protruding portion from the protective member by inserting a peeling member between the protective member and a region corresponding to the one surface of the protruding portion, after separating the second substrate from the first substrate.

In accordance with another aspect of the present invention, there is provided a manufacturing method of manufacturing a plurality of chips from a first substrate including a protruding portion formed along an outer circumferential edge and a small thickness portion having an outside surrounded by the protruding portion, the first substrate having one surface to which a protective member is fixed, the manufacturing method including setting an inner circumferential edge of a removal region in the small thickness portion, the inner circumferential edge being configured to define an external shape of a second substrate having a predetermined size, setting an outer circumferential edge of the removal region in the first substrate such that the outer circumferential edge of the removal region is located at a middle point between the inner circumferential edge of the removal region and a boundary between the small thickness portion and the protruding portion or located outward of the middle point in a radial direction of the first substrate, separating a part of the small thickness portion of the first substrate as the second substrate by removing the removal region in a thickness direction of the first substrate, and dividing the second substrate into the plurality of chips after separating the part of the small thickness portion of the first substrate as the second substrate.

In accordance with a further aspect of the present invention, there is provided a setting method of setting a removal region in a first substrate to separate, as a second substrate, a part of a small thickness portion of the first substrate including a protruding portion formed along an outer circumferential edge and the small thickness portion having an outside surrounded by the protruding portion, the first substrate having one surface to which a protective member is fixed, the setting method including setting an inner circumferential edge of the removal region in the small thickness portion, the inner circumferential edge being configured to define an external shape of the second substrate, and setting an outer circumferential edge of the removal region in the first substrate such that the outer circumferential edge of the removal region is located at a middle point between the inner circumferential edge of the removal region and a boundary between the small thickness portion and the protruding portion or located outward of the middle point in a radial direction of the first substrate.

In the manufacturing method according to one aspect of the present invention, the inner circumferential edge and the outer circumferential edge of the removal region are set in the first substrate. In particular, in setting the outer circumferential edge of the removal region in the first substrate, the outer circumferential edge of the removal region is set in the first substrate such that the outer circumferential edge of the removal region is located at the middle point between the inner circumferential edge of the removal region and the boundary between the small thickness portion and the protruding portion or located outward of the middle point in the radial direction of the first substrate. Consequently, the area of a region in which the small thickness portion remains as viewed in a plan view of the wafer is decreased as compared with a case where the outer circumferential edge of the removal region is located inward of the middle point in the radial direction of the first substrate. The remaining small thickness portion is therefore not easily cracked. Hence, it is possible to reduce a possibility of fragments of the small thickness portion being peeled off from the protective member.

The manufacturing method according to another aspect of the present invention and the setting method according to yet another aspect of the present invention can also reduce the possibility of fragments of the small thickness portion being peeled off from the protective member for similar reasons.

The above and other objects, features and advantages of the present invention and the manner of realizing them will become more apparent, and the invention itself will best be understood from a study of the following description and appended claims with reference to the attached drawings showing preferred embodiments of the invention.

### BRIEF DESCRIPTION OF THE DRAWINGS

FIG. 1 is a flowchart of a manufacturing method of manufacturing a plurality of chips;

FIG. 2A is a perspective view of the front surface side of a wafer;

FIG. 2B is a perspective view of the back surface side of the wafer;

FIG. 2C is a sectional view taken along a line A-A of FIG. 2B;

FIG. 3 is a partially sectional side view illustrating a holding step;

FIG. 4A is a diagram illustrating a removal region inner circumferential edge setting step;

FIG. 4B is a diagram illustrating a removal region outer circumferential edge setting step;

FIG. 5A is a plan view of the wafer, the plan view illustrating a removal region;

FIG. 5B is a sectional view taken along a line B-B of FIG. 5A;

FIG. 6A is a partially sectional side view illustrating an example at a time of a start of a separating step;

FIG. 6B is a partially sectional side view illustrating an example at a time of an end of the separating step;

FIG. 7A is a partially sectional side view illustrating a start of a protruding portion peeling step;

FIG. 7B is a partially sectional side view illustrating a protruding portion falling in the protruding portion peeling step;

FIG. 8 is a partially sectional side view illustrating a peeling step in the related art;

FIG. 9 is a partially sectional side view illustrating a dividing step;

FIG. 10A is a plan view of the wafer, the plan view illustrating a removal region inner circumferential edge setting step and a removal region outer circumferential edge setting step in a second embodiment; and

FIG. 10B is a sectional view taken along a line C-C of FIG. 10A.

### DETAILED DESCRIPTION OF THE PREFERRED EMBODIMENTS

### First Embodiment

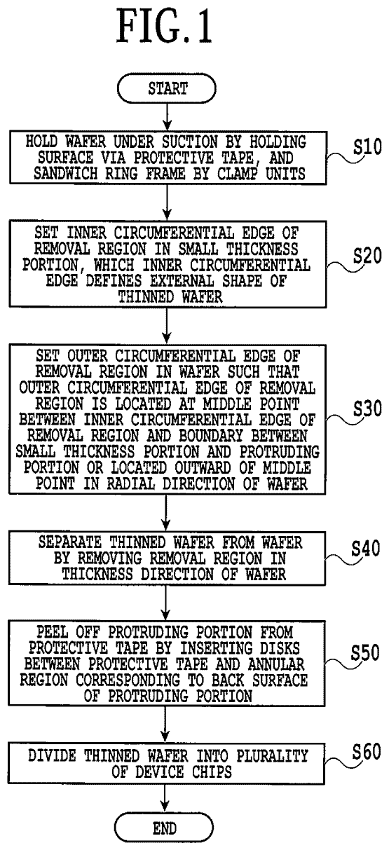

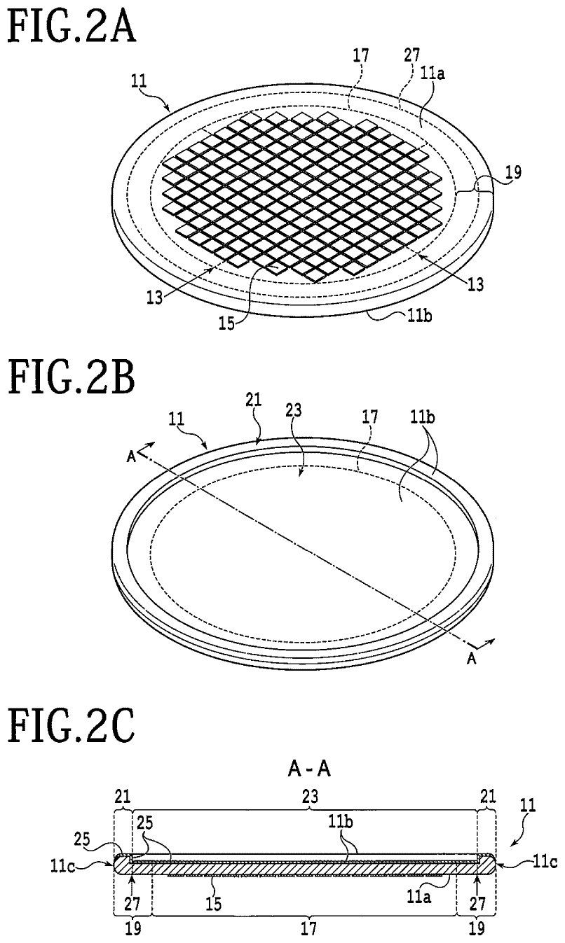

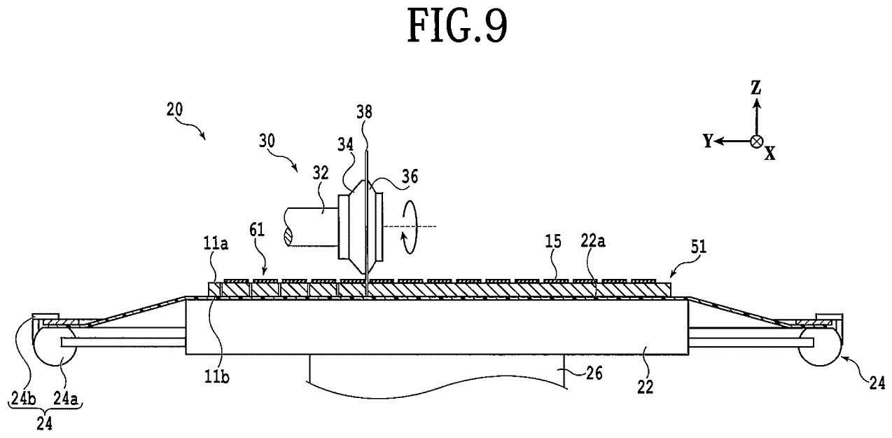

An embodiment according to one aspect of the present invention will be described with reference to the accompanying drawings. FIG. 1 is a flowchart of a manufacturing method of manufacturing a plurality of device chips (that is, chips) 61 (see FIG. 9) from a wafer (that is, a first substrate) 11 (see FIG. 2A and the like).

The first embodiment performs a holding step S10, a removal region inner circumferential edge setting step S20, a removal region outer circumferential edge setting step S30, a separating step S40, a protruding portion peeling step S50, and a dividing step S60 in this order. However, the removal region inner circumferential edge setting step S20 may be performed before the removal region outer circumferential edge setting step S30. Also, the removal region outer circumferential edge setting step S30 may be performed before the removal region inner circumferential edge setting step S20.

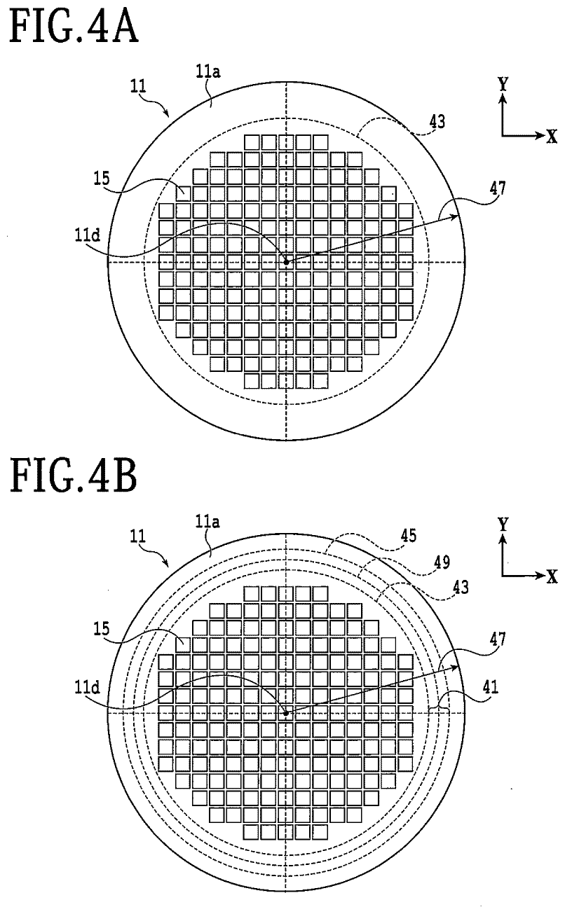

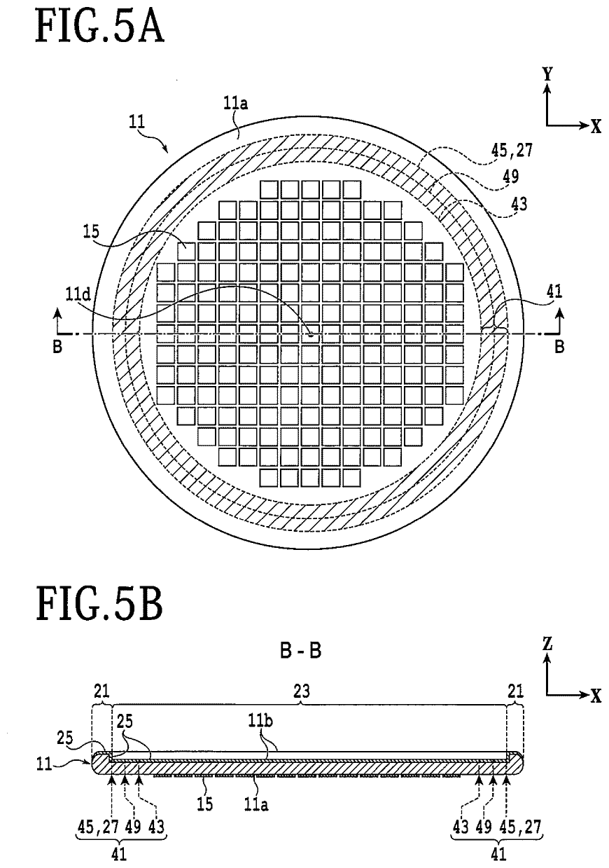

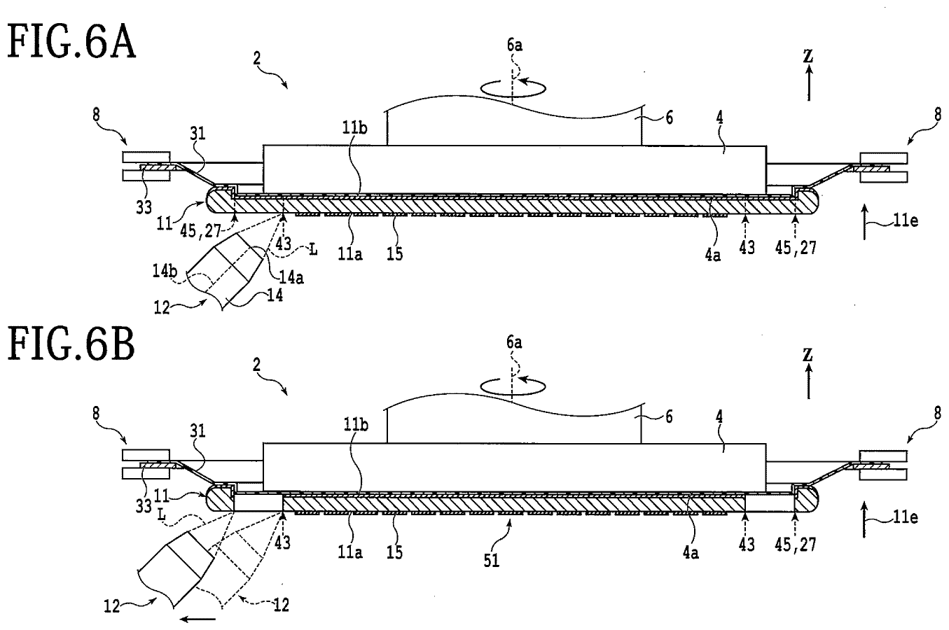

Incidentally, the flowchart illustrated in FIG. 1 includes a manufacturing method of manufacturing a thinned wafer (that is, a second substrate) 51 (see FIG. 6B and the like) by separating a part of a small thickness portion 23 (see FIG. 2C and the like) of a wafer 11 as the thinned wafer 51 and a setting method of setting a removal region 41 (see FIG. 4B, FIG. 5A, and the like) in the wafer 11.

Before the description of each step in FIG. 1, the wafer 11 as a processing target will be described with reference to FIGS. 2A to 2C. FIG. 2A is a perspective view of a front surface 11a side of the wafer 11. FIG. 2B is a perspective view of a back surface (that is, one surface) 11b side of the wafer 11. FIG. 2C is a sectional view taken along a line A-A of FIG. 2B.

The wafer 11 includes a silicon single crystal substrate in a disk shape. The thickness of the wafer 11 (that is, the thickness of a protruding portion 21 to be described later) in the present embodiment is approximately 775 μm, and the diameter of the wafer 11 is approximately 300 mm. However, the numerical values of the thickness and the diameter are an example, and are not necessarily limited to those of the present example.

In addition, the single crystal substrate constituting the wafer 11 is not limited to silicon, and may be formed by a single crystal substrate of a compound semiconductor such as silicon carbide (SiC) or gallium nitride (GaN), or may be formed by another material.

As illustrated in FIG. 2A, a plurality of planned dividing lines (that is, streets) 13 are set in a lattice manner on the front surface 11a side of the wafer 11. Incidentally, in FIG. 2A, extensions of two planned dividing lines 13 orthogonal to each other are representatively indicated by respective broken lines in consideration of the ease of viewing of the drawing.

Devices 15 such as integrated circuits (ICs) are formed in respective rectangular regions demarcated by the plurality of planned dividing lines 13. The plurality of devices 15 are arranged in a central portion in a radial direction 47 (see FIG. 4A and the like) of the wafer 11. The kind, quantity, shape, structure, size, arrangement, and the like of the plurality of devices 15 are not limited.

In the present specification, a circular region that includes the plurality of devices 15 in the front surface 11a will be referred to as a device region 17, and an annular region of the front surface 11a, which annular region is located on the outside of the device region 17 in the radial direction 47 of the wafer 11, will be referred to as a peripheral surplus region 19.

The device region 17 illustrated in FIG. 2A is a circular region concentric with the wafer 11. In FIG. 2A, the external shape of the device region 17 is indicated by a broken line. However, the external shape of the device region 17 is not indicated on an actual wafer 11. Incidentally, for the convenience of description, the external shape of the device region 17 is indicated by a broken line also in FIG. 2B.

A notch indicating a crystal orientation is not illustrated in the wafer 11 in FIG. 2A and FIG. 2B. However, a notch is formed on an actual wafer 11. In addition, depending on the size of the wafer 11, an orientation flat may be formed on the wafer 11 in place of the notch.

As illustrated in FIG. 2B and FIG. 2C, the wafer 11 includes the protruding portion 21 in an annular shape and the small thickness portion 23 in a disk shape. The protruding portion 21 is formed along an outer circumferential edge 11c of the wafer 11. The small thickness portion 23 has an outside thereof surrounded by the protruding portion 21 in the radial direction 47 of the wafer 11.

In the present embodiment, the thickness of the protruding portion 21 is 775 μm, while the thickness of the small thickness portion 23 is 100 μm. However, in consideration of the ease of viewing of the drawing, the thickness of the small thickness portion 23 is illustrated to be larger than an actual thickness in the drawing. The width of the protruding portion 21 in the radial direction 47 of the wafer 11 is 2.6 mm, for example.

A disk-shaped recessed portion defined by the protruding portion 21 and the small thickness portion 23 exists on the back surface 11b side of the wafer 11. The wafer 11 having this recessed portion is formed by subjecting a wafer defined by a predetermined standard such as Semiconductor Equipment and Materials International (SEMI) M1, for example, to processing referred to as TAIKO (registered trademark).

As illustrated in FIG. 2C, a metallic layer 25 is provided to substantially the whole of the back surface 11b of the wafer 11. The metallic layer 25 is provided to each of the back surface 11b of the protruding portion 21 (that is, an annular region on the outside of the back surface 11b), an inner circumferential wall of the protruding portion 21 (that is, a side region in a cylindrical shape), and the back surface 11b of the small thickness portion 23 (that is, a circular region in a central portion of the back surface 11b). The metallic layer 25 forms one continuous layer.

The metallic layer 25 is thin enough not to completely fill the disk-shaped recessed portion, and has a substantially uniform thickness. For example, the metallic layer 25 has a thickness of approximately 20 μm in a region excluding a bevel portion of the back surface 11b.

The metallic layer 25 has, for example, a three-layer structure of a titanium (Ti) layer, a nickel (Ni) layer, and a silver (Ag) layer. The titanium layer is in contact with the silicon single crystal substrate. The silver layer is exposed on an outermost surface. However, the structure of the metallic layer 25 is not limited to the three-layer structure. The metallic layer 25 may be formed by one layer or by two layers or four layers or more formed of materials different from each other.

In a case where the inner circumferential wall of the protruding portion 21 and the back surface 11b of the small thickness portion 23 are substantially orthogonal to each other as illustrated in FIG. 2C, the position of the outermost surface of the metallic layer 25 provided to the inner circumferential wall of the protruding portion 21 defines a boundary 27 between the protruding portion 21 and the small thickness portion 23.

As viewed in the sectional view illustrated in FIG. 2C, a connection region between the inner circumferential wall of the protruding portion 21 and the back surface 11b of the small thickness portion 23 is not limited to having a right angle, and may be formed with a smooth curve, or may be formed in a stepped shape that is thinned stepwise toward the inside in the radial direction 47 of the wafer 11.

In a case of the smooth curve or the stepped shape, the boundary 27 is, for example, a thinnest position of the connection region (that is, a position of the thickness of the small thickness portion 23). However, more preferably, the boundary 27 is the position of the outermost surface of the metallic layer 25 provided to the inner circumferential wall of the protruding portion 21.

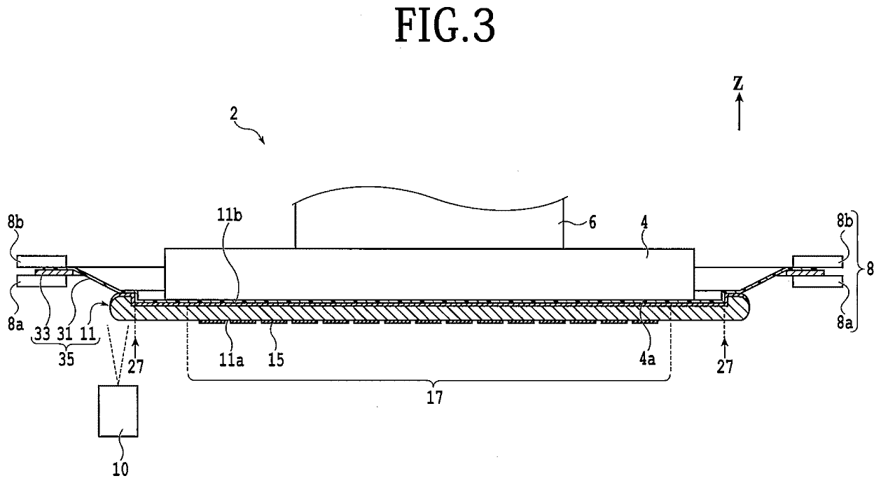

At a time of performing processing such as laser processing on such a wafer 11, first, a wafer unit 35 is formed by affixing a central portion of a circular protective tape (that is, a protective member) 31 made of resin to the back surface 11b of the wafer 11 and affixing a ring frame 33 made of metal to an outer circumferential portion of the protective tape 31 (see FIG. 3).

The protective tape 31 is affixed so as to conform to the recessed portion of the wafer 11, and is fixed to the back surface 11b of the protruding portion 21 and the small thickness portion 23 and the inner circumferential wall of the protruding portion 21. The protective tape 31 is thus fixed to substantially the whole of the back surface 11b of the wafer 11.

The protective tape 31 has, for example, a laminated structure of an adhesive layer (glue layer) and a base material layer. The adhesive layer includes an epoxy-based, acrylic-based, or rubber-based adhesive. The protective tape 31 is fixed to the wafer 11 and the like by pressing the adhesive layer of the protective tape 31 against the wafer 11 and the ring frame 33.

An epoxy resin or an acrylic resin of an ultraviolet curable type that is cured by ultraviolet rays is used as the adhesive layer in the present embodiment. However, the material of the adhesive is not limited to this as long as an adhesive force thereof can be partially reduced by light, heat, pressure, or the like. The base material layer is formed of, for example, resin such as polyolefin, polyvinyl chloride, or polyethylene terephthalate.

Processing is performed on the wafer 11 in the form of the wafer unit 35. The present embodiment performs steps from the holding step S10 to the protruding portion peeling step S50 by using a laser processing apparatus 2 (see FIG. 3). Here, the laser processing apparatus 2 will be described with reference to FIG. 3 and the like.

Incidentally, a Z-axis illustrated in drawings from FIG. 3 onward is substantially parallel with an upward-downward direction and a vertical direction. The laser processing apparatus 2 includes a holding plate 4 in a disk shape. The outside diameter of the holding plate 4 is smaller than the outside diameter of the recessed portion of the wafer 11, and is larger than the outside diameter of the device region 17.

As illustrated in FIG. 3, in the present embodiment, a holding surface 4a of the holding plate 4 is exposed downward. The holding plate 4 is what is called a chuck table that holds the wafer unit 35 under suction by a bottom surface thereof. The holding plate 4 includes a disk-shaped frame body formed of a non-porous metal or the like.

A bottom portion of the frame body is provided with a recessed portion (not illustrated). A porous body formed of a porous ceramic or the like is fixed to the recessed portion. The respective bottom surfaces of the frame body and the porous body are flush with each other, and constitute the holding surface 4a that is substantially flat. When a negative pressure is transmitted to the bottom surface of the porous body from a suction source (not illustrated) such as a vacuum pump, the wafer 11 is held under suction by the holding surface 4a.

A bottom portion of a rotary shaft 6 in a cylindrical shape is fixed to the top surface of the holding plate 4. The rotary shaft 6 is, for example, a rotor of a motor, and constitutes the motor together with a stator not illustrated. However, the rotary shaft 6 may be a shaft portion to which a driven pulley is fixed in place of the rotor. In this case, the rotary shaft 6 is rotated when power from the motor is transmitted via a driving pulley and an endless belt.

Clamp units 8 are provided to sides of the holding plate 4. The clamp units 8 include an elongated supporting member 8a in a thin plate shape, which supporting member 8a supports the ring frame 33 from below and an elongated holding member 8b in a thin plate shape, which holding member 8b holds the ring frame 33 from above.

The supporting member 8a and the holding member 8b each extend along a predetermined direction orthogonal to the Z-axis (that is, a vertical direction of a paper plane of FIG. 3). The holding member 8b is fixed to the holding plate 4. The supporting member 8a is movable along the Z-axis by an actuator (not illustrated), and can thereby approach and separate from the holding member 8b.

The position of the ring frame 33 with respect to the holding plate 4 is fixed by sandwiching the ring frame 33 from above and from below. A camera unit 10 is provided below the holding plate 4. The camera unit 10 includes an objective lens having an optical axis thereof disposed along the Z-axis and an imaging element such as a charge-coupled device (CCD) image sensor.

The camera unit 10 captures an image of the wafer 11 having the front surface 11a exposed in a downward direction by, for example, visible light from a position below the holding surface 4a. An image of the wafer 11 obtained by the imaging is used for the setting of a removal region 41 to be described later, the alignment of the wafer 11 at a time of laser processing, and the like.

Though omitted in FIG. 3, a laser beam irradiating unit 12 (see FIG. 6A) is provided below the holding surface 4a and in the vicinity of an outer circumferential portion of the holding surface 4a. The laser beam irradiating unit 12 has a laser oscillator (not illustrated).

The laser oscillator includes a laser medium such as an Nd:YAG crystal, an optical resonator, a Q-switch, and the like. When the laser medium is irradiated with excitation light from an excitation light source such as a flash lamp or a laser diode, the laser oscillator emits a pulsed laser beam due to the action of the optical resonator, the Q-switch, and the like.

The pulsed laser beam emitted from the laser oscillator is converted into a wavelength (for example, 355 nm) to be absorbed by the wafer 11, by using a nonlinear optical crystal (not illustrated). The pulsed laser beam L converted in wavelength is applied from an aperture 14a of a condenser 14 to the wafer 11, and is condensed to substantially one point of the wafer 11 by a condensing lens (not illustrated) provided within the condenser 14.

The condenser 14 and an optical axis 14b of the condenser 14 are obliquely inclined with respect to the Z-axis such that the aperture 14a faces the central side of the holding surface 4a. Specifically, the condenser 14 and the optical axis 14b are inclined such that the optical axis 14b is included in an imaginary plane including an axis 6a of the rotary shaft 6 and orthogonal to the holding surface 4a.

Thus, inclining the condenser 14 can prevent the laser beam L reflected from the wafer 11 from returning to the condenser 14 and thereby causing the operation of the laser beam irradiating unit 12 to be unstable.

It is to be noted that a manner of inclining the condenser 14 is not limited to the example illustrated in FIG. 6A. The condenser 14 may be inclined such that a plane of incidence of the laser beam L includes the axis 6a of the rotary shaft 6 and is orthogonal to the imaginary plane orthogonal to the holding surface 4a.

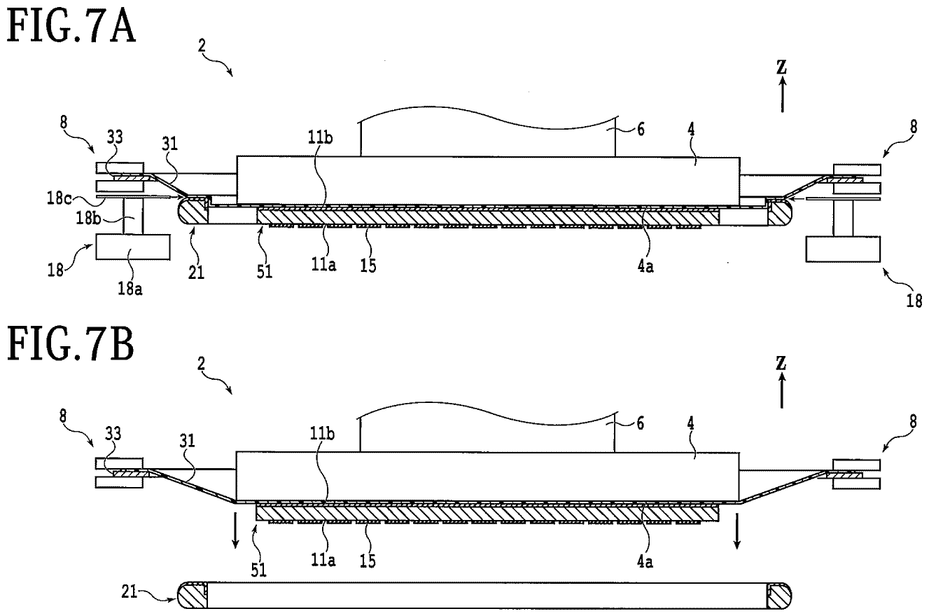

Though omitted in FIG. 3 and FIG. 6A, as illustrated in FIG. 7A, a pair of peeling units 18 is provided to sides of the holding surface 4a. The peeling units 18 include supporting bars 18a that each extend along a predetermined direction orthogonal to the Z-axis (that is, a vertical direction of a paper plane of FIG. 7A).

The supporting bars 18a are configured to be movable by an actuator such as a motor or an air cylinder so as to approach and separate from the rotary shaft 6. Two cylindrical bodies 18b are fixed to the top surfaces of the supporting bars 18a.

The two cylindrical bodies 18b are fixed to the supporting bars 18a in a manner in which the cylindrical bodies 18b are separated from each other by a predetermined distance in the above-described predetermined direction orthogonal to the Z-axis. Thin disks (that is, peeling members) 18c are fixed to the top surfaces of the cylindrical bodies 18b so as to be rotatable with respect to the cylindrical bodies 18b.

The rotational axes of the disks 18c are substantially parallel with the Z-axis. The disks 18c are inserted between the protective tape 31 and the protruding portion 21 of the wafer 11 in order to peel off the protruding portion 21 after decreasing of the adhesive force of the protective tape 31 in the annular region of the back surface 11b, which annular region corresponds to the protruding portion 21.

An ultraviolet irradiating apparatus (not illustrated) that applies ultraviolet rays downward is provided above one of the peeling units 18. The ultraviolet irradiating apparatus includes an ultraviolet (UV) lamp, a UV-light emitting diode (LED), or the like. The ultraviolet irradiating apparatus irradiates a region on the outside of the holding surface 4a in the radial direction of the holding plate 4 with ultraviolet rays from a position above the holding surface 4a.

Incidentally, the laser processing apparatus 2 is provided with a touch panel display not illustrated. The touch panel display functions as an input device for a worker to input an instruction to the laser processing apparatus 2, and functions as a display device for displaying an image captured by the camera unit 10, a graphical user interface (GUI), and the like.

Incidentally, in place of the touch panel display, a display device not having the function of the input device may be provided to the laser processing apparatus 2. In this case, however, an input device (a keyboard, a mouse, a trackball, a touch pad, a digitizer, or the like) for the worker to input an instruction to the laser processing apparatus 2 is provided separately.

A controller (not illustrated) of the laser processing apparatus 2 controls the transmission of the negative pressure from the suction source to the holding surface 4a as well as the clamp unit 8, the rotary shaft 6, the camera unit 10, the laser beam irradiating unit 12, the peeling unit 18, the ultraviolet irradiating apparatus, the touch panel display, and the like.

The controller is constituted by, for example, a computer including a processor typified by a central processing unit (CPU), a main storage device such as a dynamic random access memory (DRAM), and an auxiliary storage device such as a flash memory, a hard disk drive, or a solid-state drive.

The auxiliary storage device stores software including a predetermined program. Functions of the controller are implemented by operating the processor and the like according to the software. Next, steps from the holding step S10 to the protruding portion peeling step S50 in the laser processing apparatus 2 will be described with reference to FIGS. 3 to 7B in order.

FIG. 3 is a partially sectional side view illustrating the holding step S10. In the holding step S10, a transporting unit (not illustrated) transports the wafer unit 35 to the vicinity of the holding plate 4 in a state in which the supporting members 8a are separated downward from the holding members 8b, and the back surface 11b of the wafer 11 and the holding surface 4a are made to approach each other with the protective tape 31 interposed therebetween such that the wafer 11 covers the holding surface 4a.

Then, the wafer 11 is held under suction by the holding surface 4a by transmitting a negative pressure to the holding surface 4a, and the ring frame 33 is sandwiched by the clamp units 8 by raising the supporting members 8a. The wafer 11 is thus fixed to the holding plate 4.

After the holding step S10, a removal region 41 to be removed by ablation processing is set by using the camera unit 10. FIG. 4A is a diagram illustrating the removal region inner circumferential edge setting step S20. Incidentally, FIG. 4A illustrates a plan view of the wafer 11 when the wafer 11 is viewed from below by the camera unit 10.

An X-axis and a Y-axis are orthogonal to the Z-axis, and an XY plane is substantially parallel with a horizontal plane. In addition, in FIG. 4A, for the convenience of description, the diameter of the wafer 11 that is parallel with the X-axis and the diameter of the wafer 11 that is parallel with the Y-axis are indicated by a broken line on the front surface 11a.

In the removal region inner circumferential edge setting step S20, first, the coordinates of a center 11d of the front surface 11a of the wafer 11 are calculated. In order to calculate the coordinates of the center 11d, images of three different positions of an outer circumferential portion of the front surface 11a are obtained by, for example, alternately performing the imaging of the outer circumferential portion of the front surface 11a in the camera unit 10 and the rotation of the rotary shaft 6.

Thereafter, the coordinates of one point of the outer circumferential edge 11c of the front surface 11a are obtained in each image by image processing such as binarization processing, and the coordinates of the center of a circle (that is, the center 11d) is calculated by using the coordinates of three points of the outer circumferential edge 11c. The obtainment of the images, the image processing, the calculation of the coordinates, and the like are automatically performed by the controller.

Incidentally, the origin of the XY coordinates is the center of the holding surface 4a, for example, but is not limited to this. The controller may recognize a given point whose position does not change in the XY plane within the laser processing apparatus 2 as the origin of the XY coordinates.

After obtaining the coordinates of the center 11d, the worker sets, via the touch panel display, a region from the center 11d in the radial direction 47 of the wafer 11 (see an arrow in FIG. 4A) as the outside diameter of the thinned wafer 51 described above.

The external shape of the thinned wafer 51 is a circular shape, for example, and the outside diameter of the thinned wafer 51 is set so as to be larger by a predetermined length (for example, 1 mm, 2 mm, or the like) than a circle in which devices 15 in an outermost portion are inscribed.

An inner circumferential edge 43 of the removal region 41, which inner circumferential edge defines the external shape of the thinned wafer 51 having a predetermined size, is thus set to the small thickness portion 23 located on the inside of an outer circumferential edge 4b of the holding surface 4a. The present embodiment performs the removal region outer circumferential edge setting step S30 following the removal region inner circumferential edge setting step S20.

FIG. 4B is a diagram illustrating the removal region outer circumferential edge setting step S30. An X-axis and a Y-axis in FIG. 4B are the same as in FIG. 4A. In the removal region outer circumferential edge setting step S30, an outer circumferential edge 45 of the removal region 41 is set to the wafer 11 such that the outer circumferential edge 45 of the removal region 41 is located at a middle point 49 between the inner circumferential edge 43 of the removal region 41 and the boundary 27 or located outward of the middle point 49 in the radial direction 47 of the wafer 11.

Incidentally, because each of the inner circumferential edge 43 of the removal region 41 and the boundary 27 is a circle in the present embodiment, FIG. 4B illustrates a set of these middle points 49 in the radial direction 47 of the wafer 11 by a broken line for convenience.

In the example illustrated in FIG. 4B, the outer circumferential edge 45 of the removal region 41 is set at a position corresponding to the boundary 27 between the protruding portion 21 and the small thickness portion 23. The position corresponding to the boundary 27 is, for example, precisely the same position as the boundary 27 in the XY plane.

For example, the worker sets how many micrometers from the inner circumferential edge 43 in the radial direction 47 of the wafer 11 the position of the outer circumferential edge 45 is located by a distance from the inner circumferential edge 43 in micrometer units, via the touch panel display.

However, the boundary 27 may be located in a range from a position (start position) advanced by x % of the radius of the wafer 11 to the inside from the boundary 27 in the radial direction 47 of the wafer 11 to a position (end position) advanced by x % of the radius of the wafer 11 to the outside from the boundary 27 in the radial direction 47 of the wafer 11 (x is a given positive real number).

Incidentally, the removal region outer circumferential edge setting step S30 may set the outer circumferential edge 45 by a distance from the center 11d in the radial direction 47 of the wafer 11 or set the outer circumferential edge 45 by a distance from the boundary 27 between the protruding portion 21 and the small thickness portion 23 in place of a distance from the inner circumferential edge 43.

For example, in a case where the radius of the wafer 11 is 150 mm, the radius of the inner circumferential edge 43 (that is, the radius of the device region 17) is 145.6 mm, and the radius of the boundary 27 is 147.4 mm. Thus, the radius of the outer circumferential edge 45 is set to be equal to or more than 146.5 mm, which represents the middle point 49 between the inner circumferential edge 43 and the boundary 27.

FIG. 5A is a plan view of the wafer 11, the plan view illustrating the removal region 41 after the removal region inner circumferential edge setting step S20 and the removal region outer circumferential edge setting step S30. Incidentally, the removal region 41 is hatched for the convenience of description. FIG. 5B is a sectional view taken along a line B-B of FIG. 5A.

In the present embodiment, the removal region 41 is highlighted as illustrated in FIG. 5A on the touch panel display. Further, for example, a warning of an error or the like is displayed when there is an error such as setting the outer circumferential edge 45 on the center 11d side of the inner circumferential edge 43. Thus, when there is an error in the setting, the worker can easily notice the error. A processing defect caused by a human error can therefore be prevented.

After the removal region inner circumferential edge setting step S20 and the removal region outer circumferential edge setting step S30, the separating step S40 is performed, which removes the removal region 41 in a thickness direction 11e of the wafer 11 by ablation processing. FIG. 6A is a partially sectional side view illustrating an example at a time of a start of the separating step S40. FIG. 6B is a partially sectional side view illustrating an example at a time of an end of the separating step S40.

In the separating step S40, for example, the condenser 14 is moved outward in the radial direction of the holding surface 4a at a predetermined speed while the wafer 11 is rotated at a predetermined speed. An example of processing conditions in the separating step S40 is illustrated in the following.
Wavelength of the laser beam: 355 nm
Repetition frequency: 200 kHz
Average power: 2.0 W
Condensed spot diameter: 20 μm
Rotational speed of the holding plate: 120 rpm
Moving speed of the condenser: 0.1 mm/s

The thinned wafer 51 as a part of the small thickness portion 23 can be separated from the wafer 11 by dividing the wafer 11 into the thinned wafer 51 located directly under the holding surface 4a and the annular protruding portion 21 that remains on the outside of the holding surface 4a in the radial direction of the holding surface 4a.

In the present embodiment, the removal region outer circumferential edge setting step S30 reduces the area of a region in which the small thickness portion 23 remains after the separating step S40 as viewed in a plan view of the wafer 11 as compared with a case where the outer circumferential edge 45 of the removal region 41 is located inward of the middle point 49 in the radial direction 47 of the wafer 11. The remaining small thickness portion 23 is therefore not easily cracked. It is consequently possible to reduce a possibility of fragments of the small thickness portion 23 being peeled off from the protective tape 31.

After the separating step S40, the protruding portion peeling step S50 is performed, which peels off the protruding portion 21 located outward of the thinned wafer 51 from the protective tape 31. FIG. 7A is a partially sectional side view illustrating a start of the protruding portion peeling step S50.

In the protruding portion peeling step S50, first, the adhesive force of the adhesive layer is decreased by irradiating an annular region of the protective tape 31, which annular region is in contact with the back surface 11b of the protruding portion 21 with ultraviolet rays via the protective tape 31. However, ultraviolet rays to regions of the protective tape 31, which regions are in contact with the thinned wafer 51 and the ring frame 33, are blocked. The adhesive force in the regions is therefore maintained.

Next, the peeling units 18 are brought close to each other, and thereby the disks 18c are inserted between the protective tape 31 and an annular region corresponding to the back surface 11b of the protruding portion 21. The cured adhesive layer is destroyed by the disks 18c, or is peeled off from the protruding portion 21.

The fixation between the protruding portion 21 and the protective tape 31 is consequently released. That is, the protruding portion 21 moves relative to the thinned wafer 51 that is stationary on the holding surface 4a (that is, the protruding portion 21 falls). FIG. 7B is a partially sectional side view illustrating the protruding portion 21 falling in the protruding portion peeling step S50.

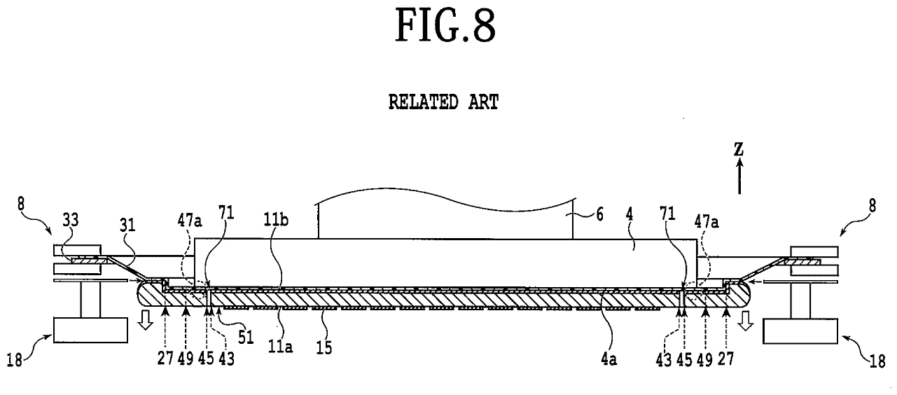

Here, an advantage of setting the removal region 41 as described above will be described. FIG. 8 is a partially sectional side view illustrating the protruding portion peeling step S50 in the related art. In the example illustrated in FIG. 8, instead of making the removal region 41 have a width sufficiently larger than the diameter of a condensing point of the laser beam L, a laser-processed groove 71 having substantially the same width as the diameter of the condensing point of the laser beam L is formed in the wafer 11.

That is, in the related art illustrated in FIG. 8, without the removal region inner circumferential edge setting step S20 and the removal region outer circumferential edge setting step S30 being set as described above, the holding plate 4 is rotated in a state in which the position of the condensing point of the laser beam L is fixed at one point, that is, the outer circumferential edge of the thinned wafer 51 (that is, the inner circumferential edge 43 of the removal region 41 described above).

In this case, a very narrow laser-processed groove 71 having substantially the same width (for example, 20 μm) as the diameter of the condensing point is formed in the wafer 11. In a case of forming such a narrow groove, as viewed in a plan view of the wafer 11, the area of a region in which the small thickness portion 23 remains in the annular region from the boundary 27 to the outer circumferential edge of the thinned wafer 51 is larger than the area of a region in which the small thickness portion 23 does not remain in the same annular region.

As a result, when the disks 18c of the peeling units 18 are inserted between the protruding portion 21 and the protective tape 31 in the protruding portion peeling step S50, a downward force acts on the protruding portion 21, and an upward force is applied to an inner circumferential portion 47a of the remaining small thickness portion 23, so that the inner circumferential portion 47a is pressed against the holding surface 4a.

The inner circumferential portion 47a of the remaining small thickness portion 23 is weak in strength due to the thinness of the inner circumferential portion 47a. Thus, in the protruding portion peeling step S50, the inner circumferential portion 47a is cracked, and fragments thereof are produced. When the fragments of the small thickness portion 23 produced at this time are peeled off from the protective tape 31 and enter the inside of the laser processing apparatus 2, the trouble of cleaning the inside of the laser processing apparatus 2 arises, consequently decreasing productivity.

In contrast, the present embodiment does not allow the small thickness portion 23 to remain on the outside of the inner circumferential edge 43 of the removal region 41 in the radial direction 47, and can therefore reduce a possibility of fragments of the small thickness portion 23 entering a processing apparatus such as the laser processing apparatus 2.

When importance is attached to the unit per hour (UPH) in the separating step S40, it is useful to form the narrow laser-processed groove 71 as illustrated in FIG. 8. However, it has been found that productivity may be decreased when fragments of the small thickness portion 23 enter the processing apparatus as described above.

The present embodiment illustrated in FIGS. 1 to 7B solves the decrease in productivity due to the fragments of the small thickness portion 23, and may decrease the UPH as compared with the method described in the related art illustrated in FIG. 8 when attention is directed to only the separating step S40. However, in view of the whole of production steps for forming a large number of wafers 11 into thinned wafers 51, there is a possibility of an improvement in the UPH in the present embodiment as compared with the related art illustrated in FIG. 8.

Incidentally, in the present embodiment, after the protruding portion peeling step S50, the thinned wafer 51 is transported to a dicing apparatus 20 (see FIG. 9), and the thinned wafer 51 is divided into a plurality of device chips 61 (dividing step S60). The dicing apparatus 20 will be described first with reference to FIG. 9.

The dicing apparatus 20 in the present embodiment is a cutting apparatus that cuts the thinned wafer 51 along the planned dividing lines 13 by a cutting blade 38 fitted to a spindle 32. However, the dicing apparatus 20 is not limited to the cutting apparatus.

The dicing apparatus 20 may be a laser processing apparatus that subjects the thinned wafer 51 to ablation processing by applying a pulsed laser beam having a wavelength to be absorbed by the thinned wafer 51, along the planned dividing lines 13.

The dicing apparatus 20 in the present embodiment has a disk-shaped chuck table 22. The chuck table 22 has substantially the same structure as that of the holding plate 4 described above. However, a holding surface 22a of the chuck table 22 is oriented upward.

On sides of the chuck table 22, a plurality of (typically four) clamp units 24 are provided at substantially equal intervals in the circumferential direction of the chuck table 22. The clamp units 24 include a pedestal portion 24a for supporting the ring frame 33 from below and a pawl portion 24b for holding the ring frame 33 from above.

An upper end portion of a rotary shaft 26 is fixed to the lower surface of the chuck table 22. The axis of the rotary shaft 26 is disposed so as to be substantially parallel with the Z-axis. The rotary shaft 26 is, for example, a rotor of a motor, and constitutes the motor together with a stator not illustrated.

However, the rotary shaft 26 may be a shaft portion to which a driven pulley is fixed in place of the rotor. In this case, the rotary shaft 26 is rotated when power from the motor is transmitted via a driving pulley and an endless belt.

The chuck table 22 and the rotary shaft 26 are supported by one moving plate (not illustrated). This moving plate is movable along the X-axis by an X-axis direction moving mechanism (not illustrated) including a ball screw and a servomotor. The X-axis direction moving mechanism is used for processing feed, for example.

A cutting unit 30 is provided above the holding surface 22a. The cutting unit 30 includes a cylindrical spindle 32 having a longitudinal direction thereof disposed along the Y-axis. A distal end portion of the spindle 32 projects to the outside of a spindle housing (not illustrated).

Another part of the spindle 32 is housed in the spindle housing. The spindle 32 is held in a rotatable manner in the spindle housing by a hydrostatic air bearing (that is, an air bearing).

The spindle 32 corresponds to a rotor constituting a motor. A stator constituting the motor is provided within the spindle housing. A mount 34 is fixed to the distal end portion of the spindle 32. The cutting blade 38 in an annular shape is sandwiched between the mount 34 and a holding flange portion 36 by fixing the holding flange portion 36 to the mount 34.

The cutting blade 38 thus fitted to the distal end portion of the spindle 32 is rotated with rotation of the spindle 32. A distal end portion of the spindle housing is provided with a cutting water supply nozzle (not illustrated) for supplying cutting water such as pure water to the cutting blade 38 in a manner in which the cutting water supply nozzle does not interfere with the cutting blade 38.

A camera unit (not illustrated) is fixed to the cutting unit 30. The camera unit is disposed above the holding surface 22a and captures an image of the wafer 11 held under suction by the holding surface 22a by using visible rays, for example. An image obtained by the imaging is used for alignment of the cutting blade 38 with a planned dividing line 13, a kerf check, and the like.

The cutting unit 30 is movable along the Y-axis and the Z-axis by a Y-axis direction moving mechanism and a Z-axis direction moving mechanism (not illustrated) each including a ball screw and a servomotor. The Y-axis direction moving mechanism performs, for example, indexing feed of the cutting blade 38. The Z-axis direction moving mechanism performs, for example, an adjustment of an amount of cutting of the cutting blade 38 into the thinned wafer 51.

A controller (not illustrated) of the dicing apparatus 20 controls the transmission of a negative pressure from a suction source to the holding surface 22a as well as the clamp unit 24, the rotary shaft 26, the X-axis direction moving mechanism, the cutting unit 30, the Y-axis direction moving mechanism, the Z-axis direction moving mechanism, and the like.

The controller is constituted by, for example, a computer including a processor typified by a CPU, a main storage device such as a DRAM, and an auxiliary storage device such as a flash memory. The auxiliary storage device stores software including a predetermined program. Functions of the controller are implemented by operating the processor and the like according to the software.

FIG. 9 is a partially sectional side view illustrating the dividing step S60. In the dividing step S60, first, the wafer unit 35 from which the protruding portion 21 and an outer circumferential portion of the small thickness portion 23 are removed is transported to the chuck table 22 by a transporting unit not illustrated, the thinned wafer 51 is held under suction by the holding surface 22a via the protective tape 31, and the ring frame 33 is sandwiched by the clamp units 24.

Next, the position of a lower end of the cutting blade 38 rotating at a high speed is adjusted to a position between the back surface 11b and the holding surface 22a. Then, the chuck table 22 is moved along the X-axis with respect to the cutting blade 38 (that is, processing feed is performed) such that the cutting blade 38 passes a planned dividing line 13 while the cutting water is supplied to the cutting blade 38.

After the thinned wafer 51 is thus cut by cutting one planned dividing line 13, the cutting unit 30 is moved along the Y-axis by a predetermined indexing feed amount (that is, a distance between planned dividing lines 13 adjacent to each other). Then, the thinned wafer 51 is cut by similarly cutting another planned dividing line 13.

After the thinned wafer 51 is cut by cutting all planned dividing lines 13 along one direction, the chuck table 22 is rotated by 90 degrees. Then, the thinned wafer 51 is cut by similarly cutting all of the remaining planned dividing lines 13. The thinned wafer 51 is thereby divided into a plurality of device chips 61.

### Second Embodiment

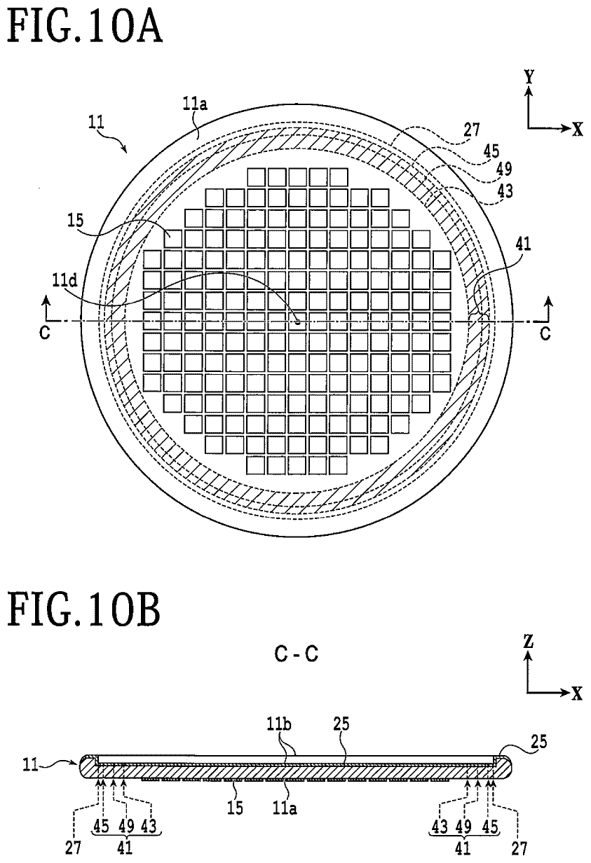

A second embodiment will next be described with reference to FIG. 10A and FIG. 10B. Also in the second embodiment, the removal region outer circumferential edge setting step S30 is performed as in the first embodiment. However, in the second embodiment, the position of the outer circumferential edge 45 is different from that in the first embodiment.

FIG. 10A is a plan view of the wafer 11, the plan view illustrating the removal region inner circumferential edge setting step S20 and the removal region outer circumferential edge setting step S30 in the second embodiment. FIG. 10B is a sectional view taken along a line C-C of FIG. 10A. The outer circumferential edge 45 in the second embodiment is not located at the boundary 27 but located between the middle point 49 and the boundary 27.

Also in the present embodiment, the removal region outer circumferential edge setting step S30 reduces the area of a region in which the small thickness portion 23 remains after the separating step S40 as viewed in a plan view of the wafer 11 as compared with a case where the outer circumferential edge 45 of the removal region 41 is located inward of the middle point 49 in the radial direction 47 of the wafer 11. The remaining small thickness portion 23 is therefore not easily cracked. It is consequently possible to further reduce the possibility of fragments of the small thickness portion 23 being peeled off from the protective tape 31.

After the separating step S40 separates the wafer 11 into the protruding portion 21 having the small thickness portion 23 on an inner circumferential portion thereof and the thinned wafer 51 by removing the removal region 41 by ablation processing, the protruding portion peeling step S50 peels off the protruding portion 21 having the small thickness portion 23 on the inner circumferential portion thereof from the protective tape 31.

Besides, structures, methods, and the like according to the foregoing embodiments can be modified and implemented as appropriate without departing from the objective scope of the present invention. Instead of making a movement trajectory of the condensing point of the laser beam L spiral as described above, the separating step S40 may make the movement trajectory of the condensing point of the laser beam L a plurality of concentric circles having respective different diameters by alternately repeating a rotation of the holding plate 4 by substantially 360 degrees and an indexing feed of moving the condenser 14 outward in the radial direction of the holding surface 4a by a predetermined amount.

In addition, the laser processing apparatus 2 can perform the separating step S40 by moving the condensing point of the laser beam L through the use of a galvanometer scanner (not illustrated) or the like while the holding plate 4 is held stationary without being rotated.

Incidentally, in the foregoing embodiments, the wafer 11 is processed in the form of the wafer unit 35 in which the protective tape 31 is fixed to the back surface 11b of the wafer 11. However, the wafer 11 may be processed in a form in which the protective tape 31 is fixed to the front surface 11a of the wafer 11.

Also in a case where the protective tape 31 is fixed to the front surface (that is, one surface) 11a of the wafer 11, steps from the holding step S10 to the protruding portion peeling step S50 can be performed by using the laser processing apparatus 2 described above. However, before the dicing apparatus 20 divides the wafer 11, the protective tape 31 is reaffixed so as to expose the front surface 11a.

Incidentally, in a case where the reaffixing of the protective tape 31 is not performed, a cutting apparatus with a special chuck table may be used. The special chuck table is formed of a material partly substantially transparent to visible light. The cutting apparatus has a function of being able to capture an image of the front surface 11a by the camera unit through the chuck table from below the chuck table holding the wafer unit 35 under suction.

Incidentally, the shape of the wafer 11 is not limited to a disk, and may be a thin plate having a given shape, such as a rectangular plate or an elliptic disk. Also in this case, the wafer 11 includes the protruding portion 21 formed along the outer circumferential edge 11c of the wafer 11 and the small thickness portion 23 having an outside thereof surrounded by the protruding portion 21 as viewed in a plan view of the wafer 11.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A manufacturing method of manufacturing a second substrate by separating, as the second substrate, a part of a small thickness portion of a first substrate including a protruding portion formed along an outer circumferential edge and the small thickness portion having an outside surrounded by the protruding portion, the first substrate having one surface to which a protective member is fixed, the manufacturing method comprising:
setting an inner circumferential edge of a removal region in the small thickness portion, the inner circumferential edge being configured to define an external shape of the second substrate;
setting an outer circumferential edge of the removal region in the first substrate such that the outer circumferential edge of the removal region is located at a middle point between the inner circumferential edge of the removal region and a boundary between the small thickness portion and the protruding portion or located outward of the middle point in a radial direction of the first substrate; and
separating the second substrate from the first substrate by removing the removal region in a thickness direction of the first substrate.

2. The manufacturing method according to claim 1, wherein,
in setting the outer circumferential edge of the removal region in the first substrate, the outer circumferential edge of the removal region is set at a position corresponding to the boundary.

3. The manufacturing method according to claim 1, further comprising:
peeling off the protruding portion from the protective member by inserting a peeling member between the protective member and a region corresponding to the one surface of the protruding portion, after separating the second substrate from the first substrate.

4. A manufacturing method of manufacturing a plurality of chips from a first substrate including a protruding portion formed along an outer circumferential edge and a small thickness portion having an outside surrounded by the protruding portion, the first substrate having one surface to which a protective member is fixed, the manufacturing method comprising:
setting an inner circumferential edge of a removal region in the small thickness portion, the inner circumferential edge being configured to define an external shape of a second substrate having a predetermined size;
setting an outer circumferential edge of the removal region in the first substrate such that the outer circumferential edge of the removal region is located at a middle point between the inner circumferential edge of the removal region and a boundary between the small thickness portion and the protruding portion or located outward of the middle point in a radial direction of the first substrate;
separating a part of the small thickness portion of the first substrate as the second substrate by removing the removal region in a thickness direction of the first substrate; and
dividing the second substrate into the plurality of chips after separating the part of the small thickness portion of the first substrate as the second substrate.

5. A setting method of setting a removal region in a first substrate to separate, as a second substrate, a part of a small thickness portion of the first substrate including a protruding portion formed along an outer circumferential edge and the small thickness portion having an outside surrounded by the protruding portion, the first substrate having one surface to which a protective member is fixed, the setting method comprising:
setting an inner circumferential edge of the removal region in the small thickness portion, the inner circumferential edge being configured to define an external shape of the second substrate; and
setting an outer circumferential edge of the removal region in the first substrate such that the outer circumferential edge of the removal region is located at a middle point between the inner circumferential edge of the removal region and a boundary between the small thickness portion and the protruding portion or located outward of the middle point in a radial direction of the first substrate.
